(19) United States
(12) Patent Application Publication
(10) Pub. No.: US 2023/0114817 A1
(43) Pub. Date: Apr. 13, 2023

(54) SEMICONDUCTOR MEASUREMENT APPARATUS

(71) Applicant: SAMSUNG ELECTRONICS CO., LTD., Suwon-si (KR)

(72) Inventors: Inho SHIN, Hwaseong-si (KR); Wookrae KIM, Suwon-si (KR); Changhyeong YOON, Suwon-si (KR); Myungjun LEE, Seongnam-si (KR); Heonju SHIN, Yongin-si (KR); Sangil IM, Suwon-si (KR); Sungho JANG, Yongin-si (KR)

(21) Appl. No.: 17/857,291

(22) Filed: Jul. 5, 2022

(30) Foreign Application Priority Data
Oct. 12, 2021 (KR) 10-2021-0134585

(51) Int. Cl. G06T 7/62; G06T 7/00

(52) U.S. Cl. CPC G06T 7/62; G06T 7/0004; G06T 2207/30148

(57) ABSTRACT

A semiconductor measurement apparatus includes an illumination unit including a light source, and a polarizer disposed on a propagation path of light emitted from the light source; an optical unit configured to direct the light passing through the polarizer to be incident onto a sample, and to transmit the light, reflected from the sample, to an image sensor; and a controller configured to process an original image, output by the image sensor, to determine a critical dimension of a structure included in a region of the sample on which the light is incident. The controller acquires a two-dimensional image. The controller orthogonally decomposes the two-dimensional image corresponding to a selected wavelength into a plurality of bases, generates one-dimensional data including a plurality of weights corresponding to the plurality of bases, and uses the one-dimensional data to determine a selected critical dimension among critical dimensions of the structure.

### CROSS-REFERENCE TO RELATED APPLICATION

This application claims benefit of priority to Korean Patent Application No. 10-2021-0134585 filed on Oct. 12, 2021, in the Korean Intellectual Property Office, the disclosure of which is incorporated herein by reference in its entirety.

### BACKGROUND

### 1. Field

Embodiments relate to a semiconductor measurement apparatus.

### 2. Description of the Related Art

A semiconductor measurement apparatus may measure a critical dimension of a structure in a sample, which includes the structure formed in a semiconductor process, using ellipsometry.

### SUMMARY

According to an embodiment, a semiconductor measurement apparatus includes an illumination unit including a light source, and a polarizer disposed on a propagation path of light emitted from the light source; an optical unit configured to incident the light passing through the polarizer onto a sample, and transmit the light, reflected from the sample, to an image sensor; and a controller configured to process an original image, output by the image sensor, to determine a critical dimension of a structure included in a region of the sample on which the light is incident, wherein the controller acquires a two-dimensional image on a back focal plane of an objective lens included in the optical unit, by processing the original image, and the controller orthogonally decomposes the two-dimensional image corresponding to a selected wavelength among wavelength bands of the light into a plurality of bases, generates one-dimensional data including a plurality of weights corresponding to the plurality of bases, and uses the one-dimensional data to determine a selected critical dimension among critical dimensions of the structure.

According to an embodiment, a semiconductor measurement apparatus includes an image sensor configured to receive light passing through a polarizer and then reflected from a sample, and generate an image representing an interference pattern of the light; an optical unit disposed on a path on which the image sensor receives the light; and a controller configured to divide the image into a first image corresponding to an intensity difference of a polarization component of the light reflected from the sample, and a second image corresponding to a phase difference of the polarization component of the light reflected from the sample, and orthogonally decompose at least one of the first image or the second image into a plurality of bases and a plurality of weights, wherein the controller uses the plurality of weights to determine a critical dimension of a structure included in a region of the sample from which the light is reflected, the light passing through the polarizer and then reflected from the sample is light having a single wavelength, and the controller receives the image from the image sensor while light having a continuous wavelength band is reflected from the sample, and acquires three-dimensional data in which the image is arranged along the wavelength band.

According to an embodiment, a semiconductor measurement apparatus includes an illumination unit including a light source, and a polarizer polarizing light emitted by the light source; an optical unit including an objective lens disposed on a path on which the light passing through the polarizer propagates toward a sample, and a polarizing element polarizing the light reflected from the sample; an image sensor configured to receive the light passing through the optical unit, and generate an original image representing an interference pattern of light in a two-dimensional plane defined at a position of a pupil of the objective lens by a single shutter operation; and a controller configured to apply orthogonal decomposition or matrix decomposition to the original image, to determine a critical dimension of a structure included in a region of the sample from which the light is reflected.

### BRIEF DESCRIPTION OF DRAWINGS

Features will become apparent to those of skill in the art by describing in detail example embodiments with reference to the attached drawings in which:

FIG. 1 is a view schematically illustrating a semiconductor measurement apparatus according to an example embodiment.

FIGS. 2 and 3A to 3C are views for describing and contrasting a method of operating a semiconductor measurement apparatus according to an example embodiment and a general semiconductor measurement apparatus.

FIGS. 4 to 6 are views illustrating respective measurement methods using a semiconductor measurement apparatus according to example embodiments.

FIG. 7 is a view schematically illustrating a semiconductor measurement apparatus according to an example embodiment.

FIG. 8 is a view illustrating a method of operating a semiconductor measurement apparatus according to an example embodiment.

FIG. 9 is a view schematically illustrating an original image acquired by a semiconductor measurement apparatus according to an example embodiment.

FIGS. 10A and 10B are views illustrating a first image and a second image extracted from an original image by a semiconductor measurement apparatus according to an example embodiment.

FIG. 11 is a view for assisting description of a method of operating a semiconductor measurement apparatus according to an example embodiment.

FIG. 12 is a view illustrating orthogonal decomposition performed in a semiconductor measurement apparatus according to an example embodiment.

FIG. 13 is a view schematically illustrating one-dimensional data generated by a semiconductor measurement apparatus according to an example embodiment.

FIGS. 14A and 14B are views for describing a method of operating a general semiconductor measurement apparatus according to a comparative example.

FIGS. 15A and 15B are views for describing of a method of operating a semiconductor measurement apparatus according to an example embodiment.

FIGS. 16A and 16B are views for describing a method of operating a semiconductor measurement apparatus according to an example embodiment.

FIGS. 17A and 17B are views for describing a method of operating a semiconductor measurement apparatus according to an example embodiment.

### DETAILED DESCRIPTION

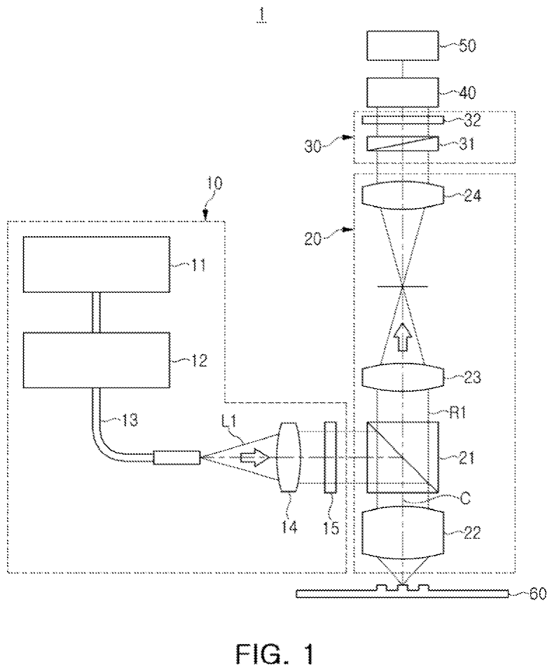

FIG. 1 is a view schematically illustrating a semiconductor measurement apparatus according to an example embodiment.

Referring to FIG. 1, a semiconductor measurement apparatus 1 according to an example embodiment may be an apparatus using or performing ellipsometry. Referring to FIG. 1, the semiconductor measurement apparatus 1 may include an illumination unit 10, an optical unit 20, a self-interference generator 30, an image sensor 40, and a controller 50. The semiconductor measurement apparatus 1 may be configured to irradiate a sample 60 using the illumination unit 10, to receive reflected light, to generate an image. The image may be analyzed to measure a critical dimension of a structure that is included in the sample 60.

The illumination unit 10 may include a light source 11, a monochromator 12, a fiber 13, an illumination lens 14, and a polarizer 15.

The light source 11 may output light to be incident to the sample 60. The light may be light including wavelengths from an ultraviolet wavelength band to an infrared wavelength band, or may be monochromatic light having a specific wavelength. The monochromator 12 may select and emit a predetermined wavelength band from light emitted by the light source 11. The monochromator 12 may irradiate light to the sample 60 while changing the wavelength band of the light from the light source 11, so as to irradiate light having a wide wavelength band or range to the sample 60.

The fiber 13 may be a cable-shaped light guide member. Light incident on the fiber 13 may be irradiated to the illumination lens 14.

The illumination lens 14 may be a convex lens. The light may be directed to be incident on the polarizer 15 by adjusting an angular distribution of the light irradiated by the fiber 13. For example, the illumination lens 14 may transform the light irradiated by the fiber 13 into parallel light.

The polarizer 15 may polarize light passing through the illumination lens 14 in a predetermined polarization direction, to be incident on the sample 60. The polarizer 15 may polarize light in a polarization direction that is inclined by 45 degrees with respect to a ground, and light passing through the polarizer 15 may propagate to a first beam splitter 21 of the optical unit 20.

The first beam splitter 21 may reflect a portion of light received through the polarizer 15, and may transmit a portion thereof.

Light reflected from the first beam splitter 21 may be incident on an objective lens 22. Light passing through the objective lens 22 may be directed to be incident on the sample 60. For example, light passing through the objective lens 22 may be incident to be focused on a target region of the sample 60. The light irradiated to the sample 60 may be linearly polarized light that is polarized in a specific direction. The linearly polarized light may be condensed and may be incident on the target region of the sample 60. The light may include a P-polarized light component and an S-polarized light component according to an incident angle determined based on the surface of the sample 60.

When the light passing through the objective lens 22 is reflected from the target region of the sample 60, the objective lens 22 may receive the reflected light again. In FIG. 1, an optical axis C of light incident on and reflected from the sample 60 is shown as being perpendicular to a surface of the sample 60. The light reflected from the sample 60 may sequentially pass through the objective lens 22, the first beam splitter 21, and first and second relay lenses 23 and 24.

The first relay lens 23 may condense light passing through the first beam splitter 21 to form an image, and may then allow the light to be incident on the second relay lens 24. The light passing through the second relay lens 24 may be incident on the self-interference generator 30.

The self-interference generator 30 may include a prism member 31 and a polarizing element 32.

The prism member 31 may separate light passing out of the optical unit 20 into light that is linearly polarized in two directions. For example, the prism member 31 may be implemented as at least one of a Nomarski prism, a Wollaston prism, or a Rochon prism. A polarization direction of each of the two directions of the linearly polarized light generated by the prism member 31 may be defined as a first direction and a second direction, perpendicular to each other.

The polarizing element 32 may transmit light to be polarized in a direction that is inclined by 45 degrees from the first and second directions. For example, the polarizing element 32 may pass a polarization component of light in a direction that is inclined by 45 degrees from the first direction, and may pass a polarization component of light in a direction that is inclined by 45 degrees from the second direction. Light passing through the polarizing element 32 may be incident on the image sensor 40.

The image sensor 40 may output an original image using received light. The original image output by the image sensor 40 may be an image including an interference pattern of light passing through the polarizing element 32. The image sensor 40 may output the original image to the controller 50, and the controller 50 may process the original image to determine a critical dimension of a structure included in a region of the sample 60 irradiated with light.

For example, the controller 50 may separate the original image into a first image and a second image. The first image may be an image indicating intensity according to polarization of light reflected from the sample 60, and the second image may be an image indicating a phase difference according to the polarization of the light reflected from the sample 60.

The controller 50 may orthogonally decompose at least one of the first image or the second image into a plurality of bases, and may use a plurality of weights allocated to the plurality of bases.

The controller 50 may use the plurality of bases and the plurality of weights, to determine a critical dimension of a structure included in a region of the sample 60 irradiated with light.

In another implementation, the controller 50 may use matrix decomposition such as singular value decomposition or the like to decompose at least one of the first image or the second image.

According to the present example embodiment, the semiconductor measurement apparatus 1 may accurately determine a selected critical dimension to be measured, among the critical dimensions of the structure of the sample 60.

In general, a critical dimension of a structure may be determined using spectrum distribution according to a wavelength of light reflected from a sample. However, in this case, a difference between the selected critical dimension to be determined and other critical dimension may affect the spectrum distribution, which may reduce measurement accuracy.

According to the present example embodiment, among a plurality of weights acquired by orthogonally decomposing at least one of a first image and a second image extracted from an original image, a selected weight having the highest sensitivity to a selected critical dimension to be measured may be determined, and the selected critical dimension may be determined with reference to the selected weight. Therefore, influence of other critical dimensions may be minimized, and performance of the semiconductor measurement apparatus 1 may be improved. Further, yield of a semiconductor process therefor may be improved.

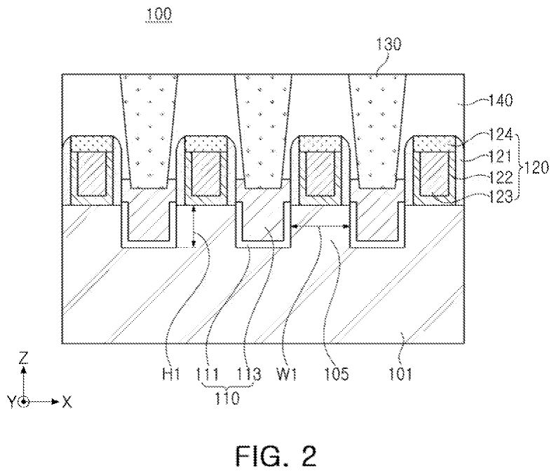

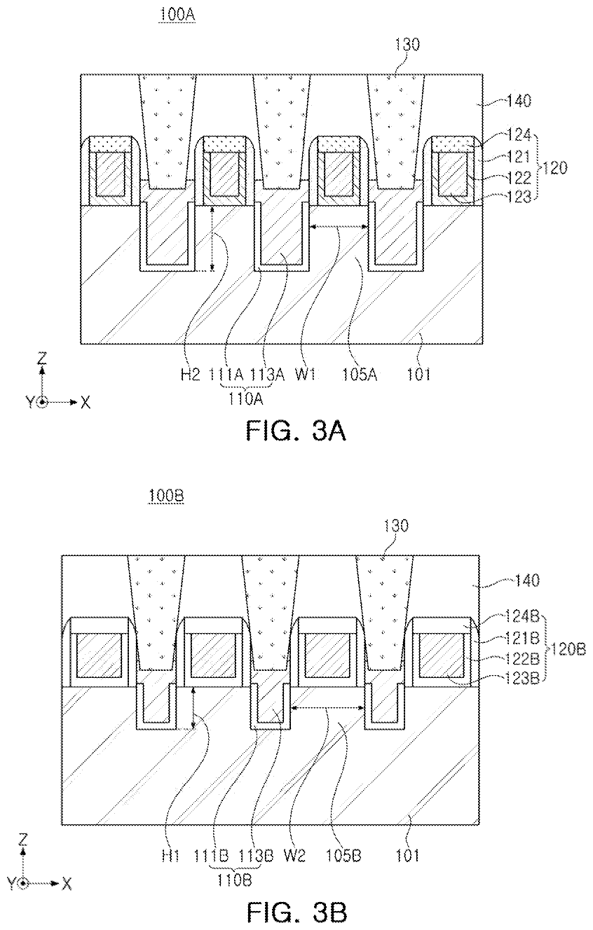

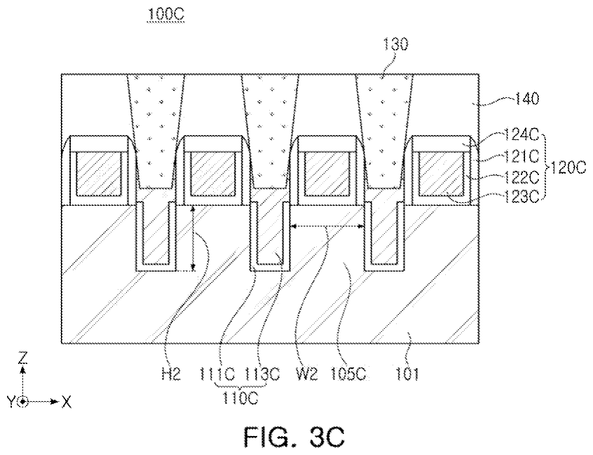

FIGS. 2 and 3A to 3C are views for describing and contrasting a method of operating a semiconductor measurement apparatus according to an example embodiment and a general semiconductor measurement apparatus.

FIGS. 2 and 3A to 3C are views schematically illustrating partial regions of semiconductor devices 100 and 100A to 100C, respectively. The semiconductor devices 100 and 100A to 100C may include a plurality of semiconductor elements. The semiconductor devices 100 and 100A to 100C may correspond to or be included in the sample 60.

Referring to FIG. 2, the semiconductor device 100 may include a substrate 101, source/drain regions 110, gate structures 120, source/drain contacts 130, and an interlayer insulating layer 140. FIG. 2 may correspond to a partial region of the semiconductor device 100, and the semiconductor device 100 may further include wiring patterns, gate contacts, a plurality of pad regions, guard patterns, or the like.

The substrate 101 may include a semiconductor material. Fin structures 105 may be formed in or on the substrate 101 to protrude in a Z-axis direction, perpendicular to an upper surface of the substrate 101. The fin structures 105 may be laterally connected to the source/drain regions 110 in an X-axis direction, and may be in contact with the gate structures 120 in a Y-axis direction and a Z-axis direction. Each of the fin structures 105 may provide a channel region.

Each of the source/drain regions 110 may include a first source/drain layer 111 and a second source/drain layer 113. The first source/drain layer 111 may be in direct contact with the substrate 101 and the fin structures 105. The second source/drain layer 113 may be a layer formed by a selective epitaxial growth process or the like using the first source/drain layer 111. The second source/drain layer 113 may be connected to the source/drain contacts 130. The source/drain contacts 130 may be disposed in the interlayer insulating layer 140, and may be formed of a material such as a metal, a metal silicide, or the like. The source/drain contacts 130 may include a plurality of layers formed of different materials.

Each of the gate structures 120 may include a gate spacer 121, a gate insulating layer 122, a gate electrode layer 123, and a capping layer 124. A semiconductor device, e.g., a transistor, etc., may be provided by one of the gate structures 120 and the source/drain regions 110 on both sides thereof.

Referring to FIG. 2, each of the fin structures 105 may have a first height H1 and a first width W1. The first height H1 and/or the first width W1 may be included among critical dimensions of the fin structures 105 that may be measured by using the semiconductor measurement apparatus 1 according to an example embodiment.

Height and widths of each of the fin structures 105 may vary according to characteristics of the semiconductor device 100.

In general, a change in width of the fin structures 105, e.g., a change in the first width W1, may affect a spectrum distribution for measuring the height of the fin structures 105, e.g., the spectrum distribution for measuring the first height H1. Therefore, in a spectrum distribution acquired to measure the heights of the fin structures 105, the spectrum distribution may be inaccurately formed, e.g., altered, by changes in the widths of the fin structures 105. As a result, an error in the measurement may occur, e.g., the dimensions may not be accurately determined.

In further detail, referring to FIG. 3A, a semiconductor device 100A may include fin structures 105A having a height that is greater than that of the fin structures 105 of FIG. 2, e.g., the fin structures 105A may have a second height H2 that is greater than the first height H1 of FIG. 2. Thus, shapes of source/drain regions 110A may be changed.

Next, referring to FIG. 3B, a semiconductor device 100B may include fin structures 105B having a width that is greater than that of the fin structures 105 of FIG. 2, e.g., the fin structures 105B may have a second width W2 that is greater than the first width W1 of FIG. 2 or FIG. 3A. Thus, shapes of source/drain regions 110B may also vary.

Next, referring to FIG. 3C, a height and a width of fin structures 105C included in a semiconductor device 100C may both increase, e.g., the fin structures 105C may have a second height H2 that is greater than the first height H1 of FIG. 2 or FIG. 3B, and a second width W2 that is greater than the first width W1 of FIG. 2 or FIG. 3A.

In general, a spectrum distribution acquired for measuring the heights of the fin structures 105 in the semiconductor device 100 of FIG. 2 may be different from each of the spectrum distributions acquired for measuring the heights of the fin structures 105A to 105C in the semiconductor devices 100A to 100C of FIGS. 3A to 3C.

As structures such as those included in the semiconductor devices 100 and 100A to 100C are increasingly miniaturized, it may become increasingly difficult to distinguish whether differences in spectrum distributions acquired from the semiconductor devices 100A to 100C occur due to a change in height, a change in width, or both. In a manufacturing process, the fin structures 105A to 105C may be formed by etching a partial region of a substrate 101. In such a process, when the heights of the fin structures 105A to 105C are desired to be increased, not only the heights but also the widths of the plurality of fin structures 105A to 105C may be changed by the etching process. In general, it may be difficult to distinguish whether a change in spectrum distribution output by a general semiconductor measurement apparatus is more influenced by a change in height or a change in width of the fin structures 105A to 105C. As a result, a desired critical dimension may not be accurately determined.

Different critical dimensions, such as a height and a width, may have different sensitivities to measurement conditions of a semiconductor measurement apparatus. For example, certain azimuth and incident angle conditions may have a sensitivity for height that is higher than a sensitivity for width.

In general, a desired critical dimension may be measured by acquiring spectrum distributions from the semiconductor devices 100A to 100C under various azimuth and incident angle conditions. However, there may be limits to azimuth and incident angle adjustments in a general semiconductor measurement apparatus.

According to an example embodiment, as described above with reference to FIG. 1, the semiconductor measurement apparatus 1 may irradiate light having an optical axis that is perpendicular to a surface of the sample 60, and may receive reflected light to determine a critical dimension of a structure included in the sample 60. According to an example embodiment, data entirely corresponding to an azimuth angle corresponding to 0 degrees to 360 degrees may be acquired by a single capturing of an image, and data corresponding to a wide range of incident angles according to a numerical aperture of an objective lens may also be acquired by a single capturing of an image. Therefore, in various azimuth and incident angles, data corresponding to the azimuth and incident angles having the highest sensitivity to a critical dimension to be measured may be selected, and the critical dimension may be determined based on a spectrum distribution thereof. Therefore, a critical dimension to be measured may be accurately determined, regardless of, or less influenced by, interaction of critical dimensions affecting each other in structures having minute dimensions, to improve efficiency of a process using the semiconductor measurement apparatus 1.

In an example embodiment, data acquired by a single capturing of an image may be orthogonally decomposed into a plurality of bases, and a critical dimension may be determined by a weight having the highest sensitivity among a plurality of weights allocated to the plurality of bases. Alternatively, the critical dimension may be determined using a distribution of the plurality of weights according to the plurality of bases. Therefore, while acquiring data of wide ranges of azimuth and incident angles by a single capturing of an image, a size of data to be processed and stored may be reduced, to efficiently perform a measurement process.

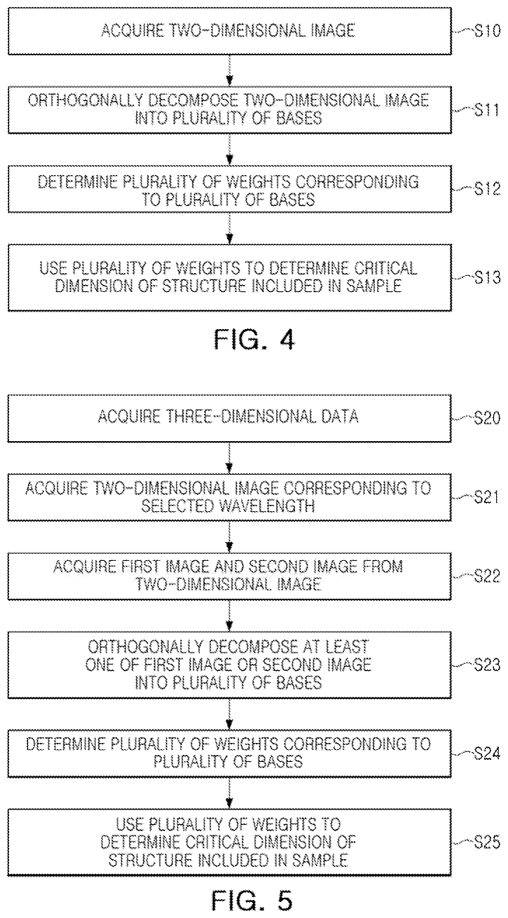

FIGS. 4 to 6 are views illustrating respective measurement methods using a semiconductor measurement apparatus according to example embodiments.

Referring to FIG. 4, an operation of a semiconductor measurement apparatus according to an example embodiment may start by acquiring a two-dimensional image (S10). The two-dimensional image acquired by a controller of the semiconductor measurement apparatus in S10 may be an original image generated by irradiating light to a sample by an illumination unit of the semiconductor measurement apparatus, and receiving the light, reflected from the sample, by an image sensor, or an image generated by processing the original image.

The controller of the semiconductor measurement apparatus may orthogonally decompose the two-dimensional image into a plurality of bases (S11). For example, the controller may orthogonally decompose the two-dimensional image using an orthogonal polynomial or matrix decomposition. The plurality of bases used for orthogonal decomposition of the two-dimensional image may be determined according to the orthogonal polynomial or the matrix decomposition, and, e.g., the orthogonal polynomial may include at least one of a Zernike polynomial, a Legendre polynomial, or a Hermite polynomial. The controller may determine a plurality of weights allocated to the plurality of bases applied to the orthogonal decomposition of the two-dimensional image (S12). Therefore, the two-dimensional image may be transformed into one-dimensional data using the plurality of bases and the plurality of weights.

The controller may use the plurality of weights to determine a critical dimension of a structure included in a region of the sample on which the light is irradiated (S13). For example, the controller may compare a distribution of the plurality of weights for the plurality of bases with reference data stored in a library, to determine the critical dimension of the structure. The reference data stored in the library may include data acquired by matching the distribution of the plurality of weights according to the plurality of bases with values of critical dimensions to be measured in the structure.

In another example embodiment, the controller may determine a selected weight, which is most sensitive to a critical dimension to be determined, from among the plurality of weights, and may compare the selected weight with the reference data stored in the library to determine the critical dimension of the structure. In this case, the reference data stored in the library may include data acquired by matching values that may have a weight having the highest sensitivity to a critical dimension to be measured in the structure with values of the critical dimension to be measured.

Referring to FIG. 5, an operation of a semiconductor measurement apparatus according to an example embodiment may start by acquiring three-dimensional data (S20), e.g., a light source included in the semiconductor measurement apparatus according to an example embodiment may irradiate a sample with light having a wavelength band from an ultraviolet wavelength band to an infrared wavelength band. While light having a wide wavelength band is reflected from the sample, an image sensor of the semiconductor measurement apparatus may generate an image representing an interference pattern of a polarization component of the reflected light, and a controller may arrange images according to wavelength bands to acquire the three-dimensional data. Here, in an XYZ coordinate system defining the three-dimensional data, an X-Y plane may be defined as a plane that is parallel to a surface of the sample, and a Z axis may be defined as an axis that is corresponding to the wavelength band.

Once the three-dimensional data is acquired, the controller of the semiconductor measurement apparatus may acquire a two-dimensional image corresponding to a selected wavelength from the three-dimensional data (S21). The three-dimensional data may include images representing an interference pattern of light reflected from the sample over a wide wavelength band or range (e.g., from an ultraviolet wavelength band to an infrared wavelength band) and, thus, when the selected wavelength is determined from the three-dimensional data, light having the selected wavelength irradiated to the sample may be acquired as the two-dimensional image.

The selected wavelength determined in S20 may be changed, depending on a configuration of a structure included in the sample and a critical dimension to be measured in the structure. For example, a wavelength having a relatively higher sensitivity, as compared to other wavelength bands, may exist, according to a direction in which the structure extends, a shape of the structure, an approximate size of the structure, and the like. Therefore, the controller may determine the selected wavelength according to the configuration of the structure included in the sample, the critical dimension to be measured in the structure, and the like. For example, even in the same structure, in measuring a height thereof and measuring a distance between the structures, the selected wavelength may be determined differently.

Also, according to an example embodiment, there may be two or more selected wavelengths. For example, the controller may select two or more selected wavelengths having a relatively higher sensitivity, as compared to other wavelength bands, with respect to a critical dimension to be measured. For example, the controller may select two or more selected wavelengths having a higher sensitivity, as compared to a predetermined reference value from the wavelength band.

The controller may acquire a first image and a second image, from the two-dimensional image acquired in S21 (S22). In an example embodiment, the first image may be an image representing an intensity ratio according to polarization of light reflected from the sample, and the second image may be an image representing a phase difference according to the polarization of the light reflected from the sample. For example, when the semiconductor measurement apparatus measures the critical dimension of the structure by using ellipsometry, the first image may correspond to a first parameter ψ of the ellipsometry according to the azimuth and incident angles, and the second image may correspond to a second parameter (Δ) of the ellipsometry according to the azimuth and incident angles.

Next, the controller may orthogonally decompose at least one of the first image or the second image into a plurality of bases (S23), and may determine a plurality of weights corresponding to the plurality of bases (S24). As described above, the controller may select a plurality of bases using at least one of an orthogonal polynomial, e.g., a Zernike polynomial, a Legendre polynomial, or a Hermite polynomial, and may determine a plurality of weights allocated to the plurality of bases. After the orthogonal decomposition, the controller may use a distribution of a plurality of weights or a selected weight, most sensitive to a critical dimension to be measured from among the plurality of weights, to determine the critical dimension of the structure (S25).

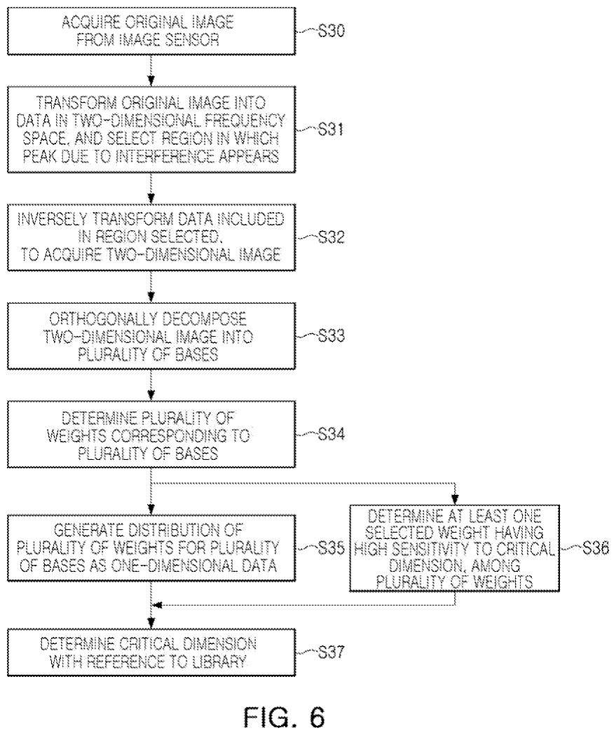

Referring to FIG. 6, an operation of a semiconductor measurement apparatus according to an example embodiment may start by acquiring an original image from an image sensor by a controller (S30). The original image may be an image generated by irradiating light to a sample by an illumination unit, and receiving light, reflected from the sample, by the image sensor. The original image may be an image in which an interference pattern of the light reflected from the sample appears. As described above with reference to FIG. 5, the controller may acquire a plurality of original images according to a wavelength band of the light irradiated to the sample by the illumination unit from the image sensor.

The controller may transform the original image into data in a two-dimensional frequency space to generate data in the frequency space, and may select a region in which a signal due to interference appears in the frequency space (S31). For example, data included in the region selected in S31 may be data corresponding to an image focused on a back focal plane set with reference to a position of a pupil of an objective lens included in an optical unit of the semiconductor measurement apparatus. The controller may inversely transform the data included in the region selected in S31, to acquire a two-dimensional image focused on the back focal plane of the objective lens by (S32). For example, a Fourier transform, a Hilbert transform, or the like may be applied to the transformation and the inverse transformation in S31 and S32.

The controller may orthogonally decompose the two-dimensional image of the back focal plane of the objective lens into a plurality of bases, and may determine a plurality of weights corresponding to the plurality of bases (S33 and S34). The plurality of bases may be determined according to at least one of an orthogonal polynomial applied to the orthogonal decomposition as described above, e.g., a Zernike polynomial, a Legendre polynomial, or a Hermite polynomial. Alternatively, the two-dimensional image may be orthogonally decomposed into the plurality of bases using matrix decomposition. When a plurality of bases and a plurality of weights corresponding to the plurality of bases are determined, the controller may use the plurality of weights to determine a critical dimension of a structure included in the sample.

For example, the controller may generate a distribution of a plurality of weights for a plurality of bases as one-dimensional data (S35). For example, the one-dimensional data may include a graph expressed on a horizontal axis corresponding to the plurality of bases and a vertical axis corresponding to the plurality of weights. The controller may compare the one-dimensional data with reference data previously stored in a library, to determine the critical dimension of the structure included in the sample (S37). In this case, the reference data may be a graph having the plurality of bases as the horizontal axis and the plurality of weights as the vertical axis, similar to the one-dimensional data generated in S35. Similarly, determining the plurality of weights according to a value of the critical dimension of the structure may be used, to compare the one-dimensional data with reference data and determine the critical dimension.

Also, according to an example embodiment, the controller may determine at least one selected weight having high sensitivity to the critical dimension, from among the plurality of weights (S36). For example, the controller may compare a predetermined first reference value with the plurality of weights, and may select at least one selected weight, greater than the first reference value. Alternatively, at least one weight having a difference from a median value or an average value, equal to or greater than a predetermined reference difference, may be selected as the selected weight with reference to the distribution of the plurality of weights.

According to an example embodiment, the controller may select one weight having the highest sensitivity to the critical dimension as the selected weight, from among the plurality of weights. Among the plurality of bases, a basis having the highest sensitivity to a critical dimension to be measured may exist. The controller may determine a weight allocated to the basis having the highest sensitivity as the selected weight. When the selected weight is determined, the controller may determine a critical dimension with reference to the reference data stored in the library (S37). In this case, the reference data may be stored by mapping a value of the critical dimension according to a value of the weight. Therefore, a critical dimension to be measured may be determined by comparing a value of the selected weight with the reference data.

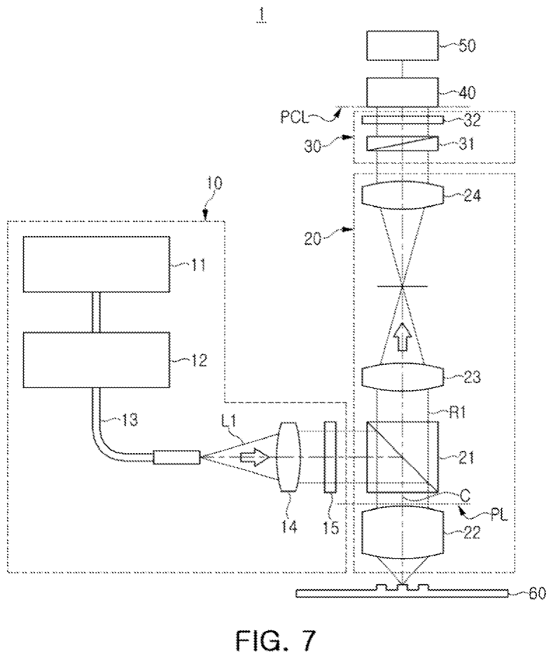

FIG. 7 is a view schematically illustrating a semiconductor measurement apparatus according to an example embodiment.

The semiconductor measurement apparatus 1 illustrated in FIG. 7 may be the same as described above with reference to FIG. 1, with FIG. 7 additionally illustrating a pupil position PL and a pupil conjugate position PCL.

The semiconductor measurement apparatus 1 may include the illumination unit 10, the optical unit 20, the self-interference generator 30, the image sensor 40, and the controller 50. Descriptions overlapping those described with reference to FIG. 1 will be omitted.

Referring to FIG. 7, a back focal plane may be defined at the pupil position PL of the objective lens 22. The back focal plane may be a plane located at a back focal length of the objective lens 22 and perpendicular to the optical axis C.

The image sensor 40 may be disposed at the pupil conjugate position PCL, which may be a conjugate with the pupil position PL. Therefore, an image may be accurately formed on a surface of the image sensor 40.

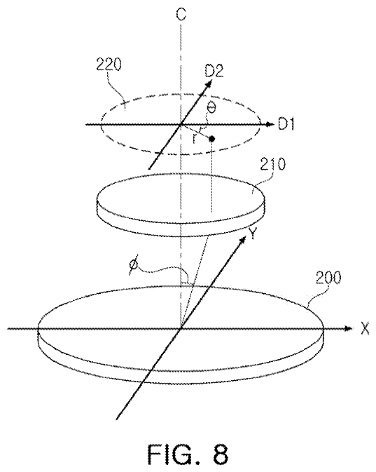

Hereinafter, an image formed on the back focal plane will be described in more detail with reference to FIG. 8.

FIG. 8 is a view illustrating a method of operating a semiconductor measurement apparatus according to an example embodiment.

Referring to FIG. 8, light may be irradiated to a surface of a sample 200.

The surface of the sample 200 to which the light is irradiated may be defined as an X-Y plane. The optical axis C may extend from an origin point of the X-Y plane, and may extend in a direction that is perpendicular to the X-Y plane. The optical axis C may pass through a center of the objective lens 210 that is disposed adjacent to the sample 200.

The objective lens 210 may include a front surface facing the sample 200 and a rear surface located opposite to the sample 200.

A back focal plane 220 may be defined at a predetermined distance from the rear surface of the objective lens 210. The back focal plane 220 may be a plane defined by a first direction D1 and a second direction D2. The first direction D1 may be the same as the X direction of a surface of the sample 200, and the second direction D2 may be the same as the Y direction of the surface of the sample 200.

Light passing through the objective lens 210 may be condensed as a dot form on a target region of the sample 200, and, after being reflected from the target region again, may pass through the objective lens 210 and may proceed to the back focal plane 220. As described above, in a semiconductor measurement apparatus according to an example embodiment, light may be incident on the sample 200 at an azimuth angle from 0 degrees to 360 degrees. An incident angle ϕ of the light incident on the sample 200 may be determined according to a numerical aperture of the objective lens 210.

In an example embodiment, the objective lens 210 employed in a semiconductor measurement apparatus may have a numerical aperture of 0.9 or more and less than 1.0, to acquire data for a wide range of incident angles in a single operation of capturing an image. In this case, a maximum incident angle of the light passing through the objective lens 210 may be 65 degrees or more, and may be less than 90 degrees.

When coordinates included in the back focal plane 220 defined in the first direction D1 and the second direction D2 are expressed as polar coordinates r and θ, as illustrated in FIG. 8, a first coordinate r may be determined by the incident angle ϕ. A second coordinate θ may be a value indicating how much the coordinates are rotated in the first direction D1, may be equal to an azimuth angle of light incident on the sample 200, and may have a value of 0 degrees to 360 degrees.

Referring to the above, in a semiconductor measurement apparatus according to an example embodiment, in a single operation of capturing an image, performed while light is reflected from the target region of the sample 200, data including an interference pattern of an incident angle range determined according to an azimuth angle of 0 degrees to 360 degrees and a numerical aperture of the objective lens 210 may be acquired in a form of an image.

Therefore, unlike a general method that uses multiple operations of capturing an image while adjusting a position and an angle of an illumination unit irradiating light on the sample 200 or a position and an angle of the sample itself, according to an example embodiment, data used for analyzing and measuring the target region of the sample 200 may be acquired in a single operation of capturing an image. Thus, efficiency of a process using a semiconductor measurement apparatus may be improved.

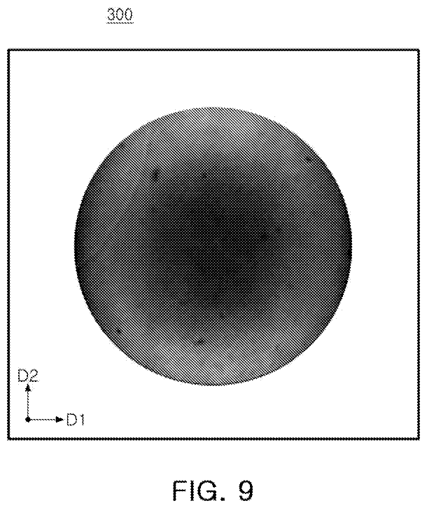

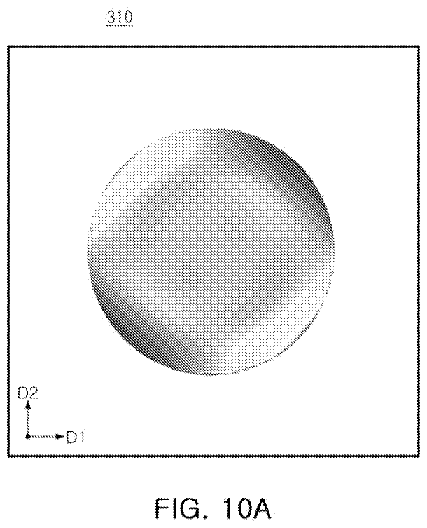

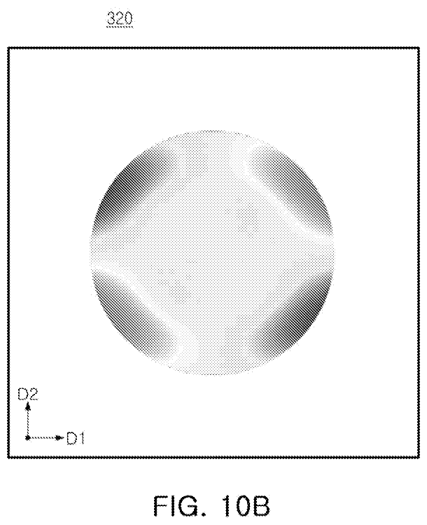

FIG. 9 is a view schematically illustrating an original image acquired by a semiconductor measurement apparatus according to an example embodiment. FIGS. 10A and 10B are views illustrating a first image and a second image extracted from an original image by a semiconductor measurement apparatus according to an example embodiment.

Referring to FIG. 9, an original image 300 may be an image acquired by an image sensor included in a semiconductor measurement apparatus in a single operation of capturing an image. The original image 300 may be expressed in a first direction D1 and a second direction D2 defining a back focal plane, and coordinates of a pixel included in the original image 300 as described above with reference to FIG. 8 may be determined by an azimuth angle and an incident angle of light.

The original image 300 may include an interference pattern of light reflected after irradiating a sample. Therefore, a first parameter ψ and a second parameter A, used for determining critical dimensions of structures included in the sample by ellipsometry, may be acquired using the original image 300.

A controller of the semiconductor measurement apparatus according to an example embodiment may extract a first image 310 corresponding to the first parameter ψ from the original image 300, and may extract a second image 320 corresponding to the second parameter A from the original image 300.

Referring to FIGS. 10A and 10B, the first image 310 and the second image 320 may be images expressed in a first direction D1 and a second direction D2, similarly to the original image 300.

The first image 310 may be an image in which an intensity ratio of signals incident on an image sensor of a semiconductor measurement apparatus is expressed according to an incident angle and an azimuth angle of light incident on a sample.

The second image 320 may be an image in which a phase difference between the signals incident on the image sensor of the semiconductor measurement apparatus is expressed according to the incident angle and the azimuth angle of the light incident on the sample.

For example, two linearly polarized signals, perpendicular to each other, may be polarized by 45 degrees by a polarizing element disposed on a front end of the image sensor in the semiconductor measurement apparatus. The first image 310 may be an image in which an intensity ratio of linearly polarized signals polarized by the polarizing element is expressed according to an incident angle and an azimuth angle. The second image 320 may be an image in which a phase difference between the linearly polarized signals polarized by the polarizing element is expressed according to the incident angle and the azimuth angle.

Referring to FIGS. 9, 10A and 10B, the original image 300, and the first image 310 and the second image 320 extracted from the original image 300, may be acquired while irradiating light having a specific wavelength band to a sample by an illumination unit of a semiconductor measurement apparatus. The wavelength band of the light irradiated to the sample by the illumination unit may be a wavelength band having high sensitivity to a configuration of a structure included in a target region of the sample to which the light is irradiated, and a critical dimension to be measured in the structure.

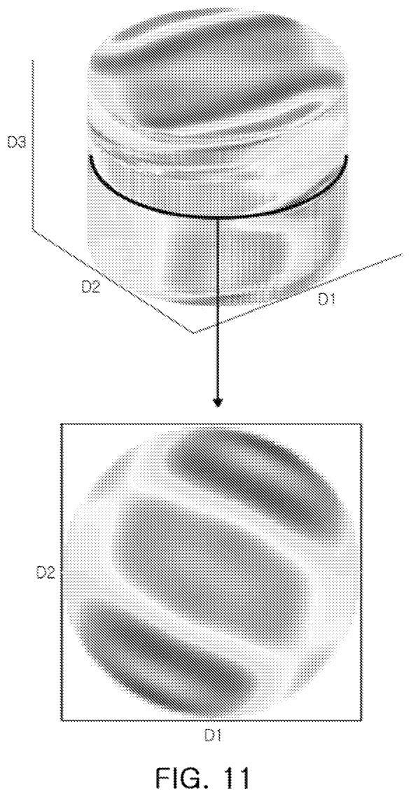

In an example embodiment, an illumination unit may irradiate light having a wavelength band of a predetermined range (not light having a specific wavelength band) to a sample, and a controller may also generate three-dimensional data including images illustrating an interference pattern of light in a wavelength band range corresponding thereto. This will now be described with reference to FIG. 11.

FIG. 11 is a view for assisting description of a method of operating a semiconductor measurement apparatus according to an example embodiment.

Referring to FIG. 11, a controller of a semiconductor measurement apparatus according to an example embodiment may generate three-dimensional data using images output from an image sensor. The three-dimensional data may include images acquired by capturing an image formed on a back focal plane, and the images may be arranged according to a wavelength band of light irradiated to a sample. Therefore, as illustrated in FIG. 11, in a space including a first direction D1 and a second direction D2, defining the back focal plane, and a third direction D3 corresponding to the wavelength band of the light, three-dimensional data may be generated.

The controller of the semiconductor measurement apparatus may determine a critical dimension of a structure included in a target region of the sample, in various manners using the three-dimensional data. For example, when an incident angle and an azimuth angle, optimized for a critical dimension to be measured in the structure, are known, coordinates corresponding to the incident angle and the azimuth angle in each of the first and second directions D1 and D2 may be specified.

When the coordinates specified in the first direction D1 and the second direction D2 are selected, the controller may acquire a spectrum distribution indicating an intensity ratio of linearly polarized signals polarized by a polarizing element in the third direction D3 corresponding to the wavelength band. In this case, the spectrum distribution acquired by the controller may be the same as a spectrum distribution generated by a general semiconductor measurement apparatus that irradiates light to a sample at predetermined incidence and azimuth angles.

In an example embodiment, each of the critical dimensions of the structure included in the target region of the sample may be quickly measured using the three-dimensional data acquired by the controller.

In a general semiconductor measurement apparatus, when an incident angle and an azimuth angle, optimized for measuring a height and a width of the structure, and an interval between structures, are different, the general semiconductor measurement apparatus may need to capture images three times while changing the incident angle and the azimuth angle.

In contrast, in an example embodiment, while irradiating light having a wide wavelength band to a sample, a controller may acquire three-dimensional data as illustrated in FIG. 11, and may acquire a spectrum distribution according to a wavelength band only by selecting an incident angle and an azimuth angle from the three-dimensional data. Thus, critical dimensions of a structure may be quickly measured.

Also, in an example embodiment, a controller may first select a specific wavelength band from three-dimensional data. When a wavelength band is first selected, as illustrated in FIG. 11, a two-dimensional image expressed on a plane defined by a first direction D1 and a second direction D2 may be acquired. In an example embodiment, two-dimensional image may be an image representing an intensity ratio and/or a phase difference of linearly polarized signals.

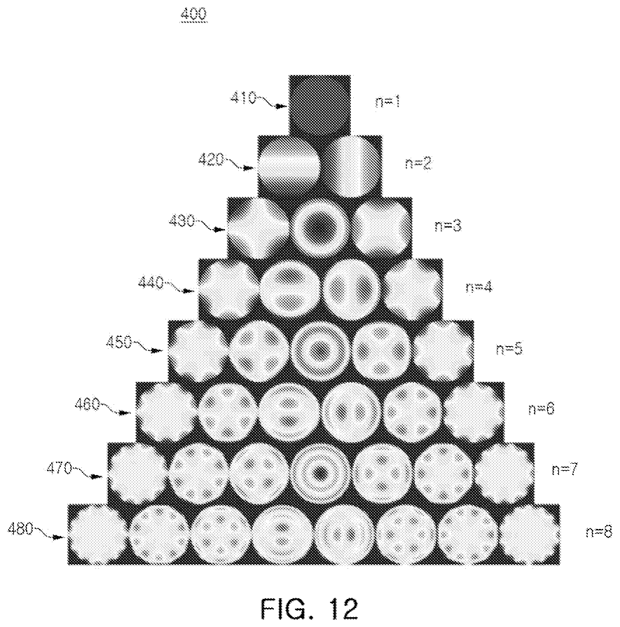

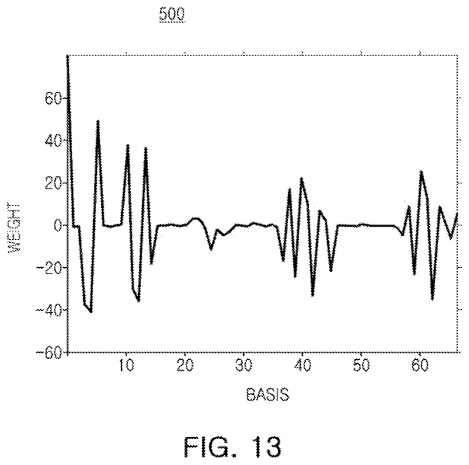

The controller may orthogonally decompose a two-dimensional image into a plurality of bases to transform the two-dimensional image into one-dimensional data, in order to lower dimension of data and reduce capacity. When the two-dimensional image is orthogonally decomposed into the plurality of bases, the two-dimensional image may be expressed as one-dimensional data including a plurality of bases and a plurality of weights corresponding to the plurality of bases. Therefore, efficiency of processing data may increase and an amount of memory required to store data acquired from a sample may decrease, at the same time. This will now be described in more detail with reference to FIGS. 12 and 13.

FIG. 12 is a view illustrating orthogonal decomposition performed in a semiconductor measurement apparatus according to an example embodiment. FIG. 13 is a view schematically illustrating one-dimensional data generated by a semiconductor measurement apparatus according to an example embodiment.

In an example embodiment, a controller of a semiconductor measurement apparatus may use at least one of a Zernike polynomial, a Legendre polynomial, or a Hermite polynomial for orthogonal decomposition of a two-dimensional image, to determine a plurality of bases. In the example embodiment illustrated in FIG. 12, a controller may orthogonally decompose a two-dimensional image into a plurality of bases 400 using a Zernike polynomial. In an example embodiment, the orthogonally decomposed two-dimensional image may be an image representing an intensity ratio and/or a phase difference of polarized signals in a predetermined wavelength band.

Referring to FIG. 12, the plurality of bases 400 according to the Zernike polynomial may be classified according to a degree, and the number of the plurality of bases applied to the orthogonal decomposition may be also changed according to a degree. For example, the plurality of bases 400 may be divided into a 1^{st} basis 410 to an 8^{th} basis 480 according to a degree, and when the degree is N, the 1^{st} to 8^{th} bases may be applied to the orthogonal decomposition. Therefore, when the degree is N, the number of bases applied to the orthogonal decomposition may be N*(N+1)/2. As the degree increases, an error between one-dimensional data acquired by the orthogonal decomposition and a two-dimensional image before the orthogonal decomposition may decrease.

In an example embodiment, the controller may orthogonally decompose a two-dimensional image representing an intensity ratio and/or a phase difference of a polarization component of light as set forth in Equation 1:

$$W ( r , θ ) = {\sum }_{n , m} {a}_{n m} {Z}_{n}^{m} ( r , θ ) \qquad [ Equation 1 ]$$

In Equation 1, W may be a two-dimensional image expressed in a first direction D1 and a second direction D2, as described above with reference to FIG. 8. As described with reference to FIG. 8, coordinates of a pixel included in the two-dimensional image may include a first coordinate r corresponding to an incident angle of light incident on a sample and a second coordinate θ corresponding to an azimuth angle of the light incident on the sample. In Equation 1, Zₙ^{m} may be a plurality of bases selected from a Zernike polynomial, and aₙₘ may be a weight allocated to the plurality of bases. Also, in Equation 1, n may be a degree applied to orthogonal decomposition, and m may be bases included in each degree.

FIG. 13 is a graph illustrating one-dimensional data 500 acquired by orthogonally decomposing a two-dimensional image by a controller of a semiconductor measurement apparatus according to an example embodiment. The one-dimensional data 500 illustrated in FIG. 13 may be expressed as a graph on coordinates having a plurality of bases as a horizontal axis and a plurality of weights allocated to the plurality of bases as a vertical axis.

In an example embodiment illustrated in FIG. 13, the controller may determine a degree for orthogonal decomposition as 12, and therefore, among bases defined in a Zernike polynomial, a two-dimensional image may be orthogonally decomposed to 66 bases included in 1^{st} to 12^{th} degrees. Weights allocated to each of the 66 bases may be determined as illustrated in FIG. 13, and a minimum weight may be allocated to a fifth basis, and a maximum weight may be allocated to a sixth basis.

The controller may use the one-dimensional data 500 generated as illustrated in FIG. 13 to determine a selected critical dimension among critical dimensions of a structure included in a target region of a sample. For example, when the selected critical dimension among the critical dimensions of the structure is changed, the two-dimensional image acquired by the controller may be changed. Therefore, the one-dimensional data acquired by orthogonally decomposing the two-dimensional image by the same degree may also be changed. For example, as the selected critical dimension is changed, a weight allocated to at least one basis among the bases may appear differently.

Therefore, the controller may compare the one-dimensional data 500 with reference data stored in a library, to measure the selected critical dimension among the critical dimensions of the structure. Referring to FIG. 13, the library may include a graph expressed in coordinates having a plurality of bases as a horizontal axis and a plurality of weights allocated to the plurality of bases as a vertical axis, as reference data.

In addition, in an example embodiment, the controller may determine a selected weight having the highest sensitivity to a selected critical dimension to be measured in the structure among the plurality of weights, and may use a value of the selected weight to determine the selected critical dimension. Alternatively, according to an example embodiment, at least one weight having sensitivity to the selected critical dimension, equal to or greater than a predetermined first reference value, may be selected as the selected weight. In this case, the library may store values of a critical dimension matching values of a basis having the highest sensitivity to the critical dimension of the structure and values of a weight allocated to the basis.

As a degree of integration of a semiconductor device increases and a structure therein becomes miniaturized thereby, at least a portion of critical dimensions defining a configuration and/or a shape of the structure may be influenced by each other in a process. For example, when a width of the structure is desired to increase, a height thereof may increase together, or when the width is desired to decrease, the height may increase. Therefore, the selected weight may be selected as a weight for a basis having low sensitivity to a critical dimension, other than a selected critical dimension, and high sensitivity to only the selected critical dimension. In an example embodiment, with respect to the critical dimension other than the selected critical dimension, a weight for a basis having lower sensitivity than a second reference value, different from a first reference value, may be selected as the selected weight.

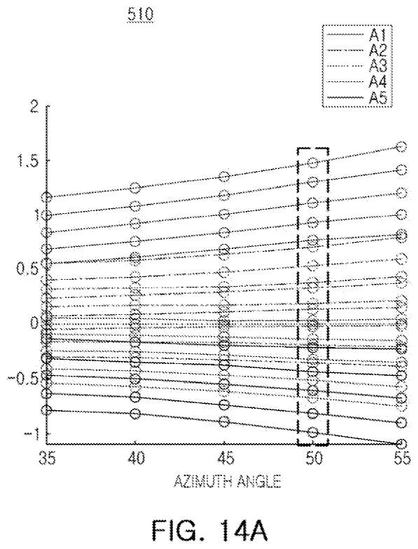

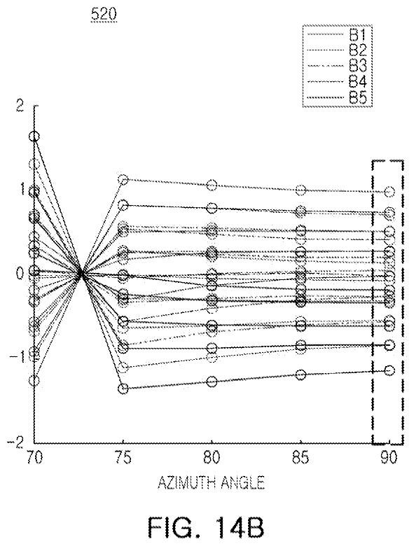

FIGS. 14A and 14B are views for describing a method of operating a general semiconductor measurement apparatus according to a comparative example.

Measurement results 510 and 520 illustrated in FIGS. 14A and 14B may be results of measuring critical dimensions of a structure included in a semiconductor device by a semiconductor measurement apparatus according to a comparative example. For example, a first measurement result 510 may be a result of measuring a first critical dimension of the structure while adjusting an azimuth angle of light irradiated to the semiconductor device in a range of 35 to 55 degrees, and a second measurement result 520 may be a result of measuring a second critical dimension of the structure while controlling the azimuth angle of the light in a range of 70 to 90 degrees. In each of the measurement results 510 and 520, a vertical axis may correspond to an intensity difference of a polarization component of light reflected from the semiconductor device.

In the semiconductor measurement apparatus according to the comparative example, data covering all azimuth angles and a wide range of incident angles may not be acquired in a single operation of capturing an image, unlike a semiconductor measurement apparatus according to an example embodiment. Therefore, as illustrated in the first measurement result 510 and the second measurement result 520, it may be necessary to acquire the data by directly changing the azimuth angles and executing a plurality of operations of capturing an image.

The first measurement result 510 of FIG. 14A may be divided into first to fifth groups A1 to A5. The first to fifth groups A1 to A5 may be determined according to values that a first critical dimension may have. For example, the first group A1 may correspond to a case in which a first critical dimension is a first value, and the fourth group A4 may correspond to a case in which a first critical dimension is a fourth value.

Also, each of the first to fifth groups A1 to A5 may include five individual graphs. The individual graphs included in each of the first to fifth groups A1 to A5 may correspond to a case in which first critical dimensions therein are the same and second critical dimensions therein are different. For example, five individual graphs included in the first group A1 may be matched to cases in which a first critical dimension is a first value and a second critical dimension is first to fifth values. Similarly, five individual graphs included in the third group A3 may be matched to cases in which a first critical dimension is a third value and a second critical dimension is first to fifth values.

Referring to FIG. 14A, in the semiconductor measurement apparatus according to the comparative example, it may be difficult to distinguish influence of a first critical dimension and a second critical dimension on each other, even when measurement is performed while changing an azimuth angle. Referring to FIG. 14A, an azimuth angle at which a first critical dimension may be best distinguished may be 50 degrees within a range of 35 to 55 degrees, but even in a measurement result measured at the azimuth angle of 50 degrees, it is not possible to accurately determine a first critical dimension due to influence of a second critical dimension. For example, a measurement result when a first critical dimension is a second value and a second critical dimension is a fifth value may be barely distinguishable from a measurement result when a first critical dimension is a third value and a second critical dimension is a third value.

A similar problem may occur in the comparative example illustrated in FIG. 14B. The second measurement result 520 of FIG. 14B may be divided into first to fifth groups B1 to B5. The first to fifth groups B1 to B5 may be determined according to values that a second critical dimension may have. Each of the first to fifth groups B1 to B5 may include five individual graphs indicating a case in which second critical dimensions therein are the same and first critical dimensions therein are different.

Referring to FIG. 14B, an azimuth angle at which a second critical dimension may be best distinguished may be 90 degree, but even in a measurement result measured at the azimuth angle of 90 degree, it is not possible to accurately determine a second critical dimension due to influence of a first critical dimension. For example, a measurement result when a first critical dimension is a fourth value and a second critical dimension is a fifth value may be barely distinguishable from a measurement result when a first critical dimension is a fifth value and a second critical dimension is a fourth value.

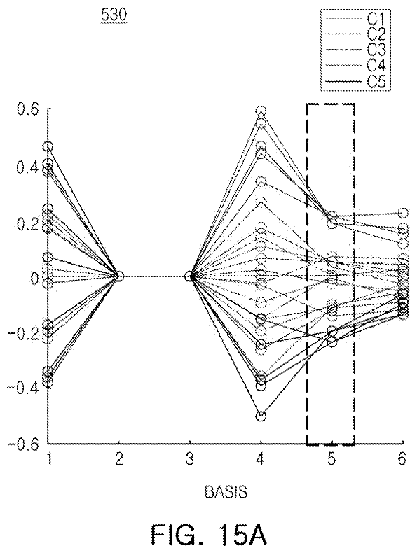

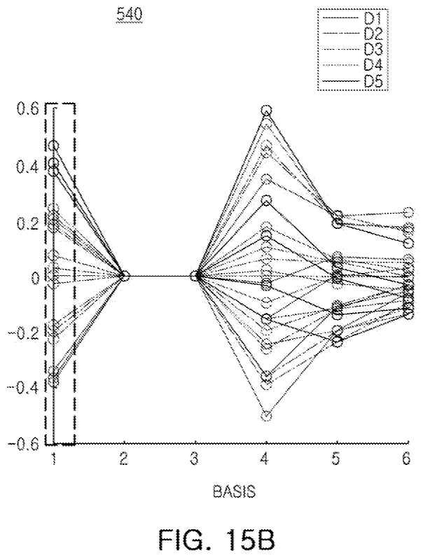

FIGS. 15A and 15B are views for describing of a method of operating a semiconductor measurement apparatus according to an example embodiment.

Referring to FIGS. 15A and 15B, measurement results 530 and 540 may be results of measuring critical dimensions of a structure included in a semiconductor device by a semiconductor measurement apparatus according to an example embodiment.

The first measurement result 530 and the second measurement result 540 may be expressed on a two-dimensional plane having a plurality of bases used to orthogonally decompose an image output by the semiconductor measurement apparatus, as a horizontal axis. For example, a vertical axis of the two-dimensional plane may correspond to an intensity difference according to polarization of light reflected from the semiconductor device, and a plurality of weights allocated to the plurality of bases may be changed due to the intensity difference according to the polarization of the reflected light.

The first measurement result 530 illustrated in FIG. 15A may be a result of measuring a first critical dimension, as in the comparative example described with reference to FIG. 14A. The first measurement result 530 may be divided into first to fifth groups C1 to C5 corresponding to first to fifth values that a first critical dimension may have. In addition, each of the first to fifth groups C1 to C5 may include five individual graphs representing a case in which second critical dimensions therein are different.

Referring to FIG. 15A, an intensity difference according to polarization of light reflected from the semiconductor device may have the highest sensitivity with respect to a first critical dimension in a fifth basis. For example, a fifth weight allocated to the fifth basis may be greatly influenced by a first critical dimension, and may be relatively less affected by a second critical dimension. For example, when a first critical dimension is a first value, the first group C1 may be clearly distinguished from the second to fifth groups C2 to C5 in the fifth basis.

A controller of the semiconductor measurement apparatus may separate an original image output by an image sensor into a first image and a second image, to measure a first critical dimension among the critical dimensions of the structure included in the semiconductor device. For example, the first image may be an image representing an intensity difference of a polarization component of light reflected from the semiconductor device, and the second image may be an image representing a phase difference in the polarization component of the light reflected from the semiconductor device. For example, the controller may orthogonally decompose the first image into a plurality of bases, and determine a plurality of weights allocated to the plurality of bases. The controller may compare a fifth weight allocated to a fifth basis with reference data previously stored in a library, to measure a first critical dimension of the structure. For example, when the fifth weight is about 0.2, the controller may determine a first critical dimension as a first value, and when the fifth weight is about −0.1, the controller may determine a first critical dimension as a fourth value.

The second measurement result 540 illustrated in FIG. 15B may be a result of measuring a second critical dimension as in the comparative example described with reference to FIG. 14B. The second measurement result 540 may be divided into first to fifth groups D1 to D5 corresponding to first to fifth values that a second critical dimension may have. Each of the first to fifth groups D1 to D5 may include five individual graphs representing a case in which first critical dimensions therein are different.

Referring to FIG. 15B, an intensity difference according to polarization of light reflected from the semiconductor device may have the highest sensitivity with respect to a second critical dimension in a first basis. For example, a first weight allocated to the first basis may be greatly influenced by a second critical dimension, and may be relatively less affected by a first critical dimension. Referring to FIG. 15B, in the second measurement result 540, individual graphs included in each of the first to fifth groups D1 to D5 may be best distinguished based on the first basis.

When measuring a second critical dimension among critical dimensions of a structure included in the semiconductor device, a controller of the semiconductor measurement apparatus may separate an original image output by an image sensor into a first image and a second image. For example, the first image may be an image representing an intensity difference of a polarization component of light reflected from the semiconductor device, and the second image may be an image representing a phase difference in the polarization component of the light reflected from the semiconductor device. The controller may orthogonally decompose the first image into a plurality of bases, and determine a plurality of weights allocated to the plurality of bases. The controller may compare a first weight allocated to a first basis with reference data previously stored in a library, to measure a first critical dimension of the structure. For example, when the first weight is about 0.4 to 0.5, the controller may determine a second critical dimension as a first value, and when the first weight is about 0.2 to 0.3, the controller may determine a first critical dimension as a second value.

Referring to FIGS. 15A and 15B, in an example embodiment, a plurality of bases and a plurality of weights acquired by orthogonally decomposing a first image representing an intensity difference of a polarization component of light reflected from a sample and/or a second image representing a phase difference thereof may be used to accurately determine a critical dimension to be measured from structures of the sample. In particular, in a process of forming a structure, only a selected critical dimension to be measured among two or more critical dimensions affecting each other may be accurately measured, to improve performance of a semiconductor measurement apparatus and improve efficiency of a process using the semiconductor measurement apparatus.

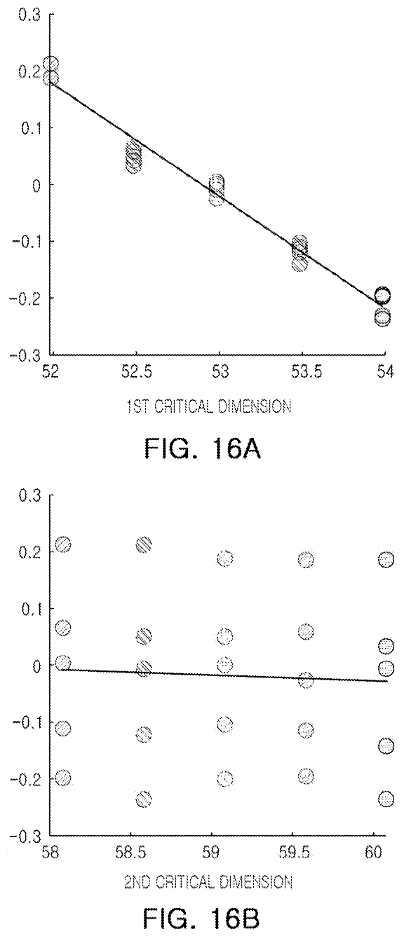

FIGS. 16A and 16B are views for describing a method of operating a semiconductor measurement apparatus according to an example embodiment.

Referring to FIGS. 16A and 16B, graphs 550 and 560 may illustrate sensitivity of a fifth basis with respect to a first critical dimension and a second critical dimension in the first measurement result 530 described with reference to FIG. 15A.

When a first image representing an intensity difference of a polarization component of light reflected from a semiconductor device is orthogonally decomposed, the highest sensitivity with respect to a first critical dimension in a fifth basis may appear. Referring to FIG. 16A, when the first critical dimension is 52 nm, the intensity difference of the polarization component of the light may have a value of about 0.2 in the fifth basis. A change in second critical dimension, different from the first critical dimension, may affect an interference pattern of the light, to change an original image output by an image sensor of a semiconductor measurement apparatus. Therefore, a value of a fifth weight may be defined as a predetermined range. Similarly, when the first critical dimension is 53.5 nm, the fifth weight may have a value of about −0.1.

As illustrated in a trend line illustrated in the graph 550 of FIG. 16A, the intensity difference of the polarization component of the light may have a high sensitivity with respect to the first critical dimension in the fifth basis, and as a value of the first critical dimension changes, the fifth weight allocated to the fifth basis may also vary greatly. Therefore, the controller of the semiconductor measurement apparatus may orthogonally decompose the first image representing the intensity difference of the polarization component of the light, and may compare the fifth weight allocated to the fifth basis as a result of the orthogonal decomposition with reference data stored in a library, to accurately measure a first critical dimension.

The intensity difference of the polarization component of the light reflected from the semiconductor device may have high sensitivity with respect to the second critical dimension in a basis, other than the fifth basis, e.g., in a first basis. Therefore, as illustrated in the graph 560 of FIG. 16B, the intensity difference of the polarization component of the light in the fifth basis may not be appropriate for measuring the second critical dimension.

For example, when the second critical dimension is 58 nm and the first image representing the intensity difference of the polarization component of the light reflected from the semiconductor device is orthogonally decomposed, the fifth weight allocated to the fifth basis may have values between about 0.2 to about −0.2. When the second critical dimension is 58 nm, the first critical dimension is 52 nm, and an image representing the intensity difference of the polarization component of the light is orthogonally decomposed, the fifth weight allocated to the fifth basis may be 0.2. When the second critical dimension is 58 nm, the first critical dimension is 54 nm, and an image representing the intensity difference of the polarization component of the light is orthogonally decomposed, the fifth weight allocated to the fifth basis may be −0.2. Therefore, the controller of the semiconductor measurement apparatus may not determine the second critical dimension as the fifth basis, among the plurality of bases used to orthogonally decompose the first image.

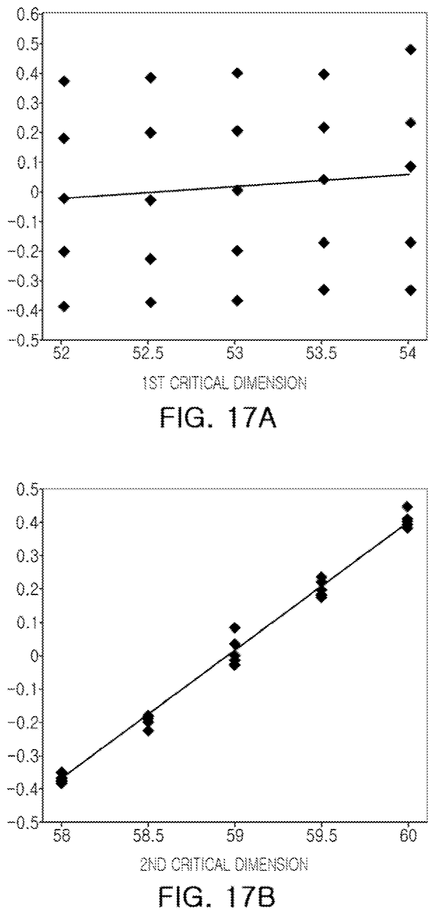

FIGS. 17A and 17B are views for describing a method of operating a semiconductor measurement apparatus according to an example embodiment.

FIGS. 17A and 17B may be graphs 570 and 580 illustrating sensitivity of a first basis with respect to a first critical dimension and a second critical dimension in the first measurement result 530 described with reference to FIG. 15A.

When a first image representing an intensity difference of a polarization component of light reflected from a semiconductor device is orthogonally decomposed, the first image may be expressed by a plurality of bases and a plurality of weights allocated to the plurality of bases. The intensity difference of the polarization component of the light reflected from the semiconductor device may be expressed as the first image. When a first critical dimension of a structure included in the semiconductor device is 52 nm, and the first image is decomposed into a plurality of bases, a first weight of −0.4 to 0.4 may be allocated to a first basis as illustrated in FIG. 17A. Similarly, for values of the first critical dimension, the first weight allocated to the first basis may be distributed over a relatively wide range. As a result, it can be seen that the first basis has low sensitivity with respect to the first critical dimension, and the controller of the semiconductor measurement apparatus may not use the first weight allocated to the first basis to measure the first critical dimension.

The first basis may have a high sensitivity with respect to the second critical dimension. Referring to FIG. 17B, an intensity difference of a polarization component of light reflected from a semiconductor device may have a tendency to greatly depend on the second critical dimension in a first basis. Referring to FIG. 17B, when a first image representing an intensity difference of a polarization component of light reflected from a semiconductor device having a second critical dimension of 58 nm of a structure is orthogonally decomposed, the first weight corresponding to the first basis may be determined in a range of 0.35 to −0.4. Similarly, when a first image representing an intensity difference of a polarization component of light reflected from a semiconductor device having a second critical dimension of 59.5 nm of a structure is orthogonally decomposed, the first weight corresponding to the first basis may be determined in a range of 0.18 to 0.24.

In summary, like a trend line illustrated in the graph 580 of FIG. 17B, when the intensity difference of the polarization component of the light is orthogonally decomposed, the first basis may have high sensitivity with respect to the second critical dimension, and as a value of the second critical dimension change, the first weight allocated to the first basis may also changes significantly. Therefore, a controller of the semiconductor measurement apparatus according to an example embodiment may orthogonally decompose the first image representing the intensity difference of the polarization component of the light, and may compare the first weight allocated to the first basis as a result of the orthogonal decomposition with reference data stored in a library, to accurately measure a second critical dimension.

In example embodiments described with reference to FIGS. 16A to 17B, a controller of a semiconductor measurement apparatus may orthogonally decompose a first image representing an intensity difference of a polarization component of light, and as a result of the orthogonal decomposition, a plurality of bases and a plurality of weights allocated to the plurality of basis may be acquired. The controller may determine a critical dimension by selecting one of the plurality of weights according to a critical dimension to be measured and comparing the same with reference data of a library. For example, the reference data of the library may be data stored by matching a value of the critical dimension according to a value of each of the plurality of weights, and in this case, a value of each of the plurality of weights may not be a single value, but may be defined in a predetermined range. According to example embodiments, the controller may orthogonally decompose a second image representing a phase difference of the polarization component of the light, and may use a weight allocated to a basis most sensitive to a critical dimension to be measured, among a plurality of bases, as a result of the orthogonal decomposition, to determine a critical dimension.

By way of summation and review, ellipsometry may involve irradiating light to a sample at fixed azimuth and incident angles, and may use a spectrum distribution of the light reflected from the sample to determine a critical dimension of a structure included in a region of the sample to which the light is irradiated. As the critical dimension of the structure formed by a semiconductor process gradually decreases, an effect of a change in a critical dimension, other than the critical dimension to be measured, on the spectrum distribution may increase. Accordingly, the critical dimension to be measured may not be accurately determined.

As described above, embodiments may provide a semiconductor measurement apparatus capable of acquiring data for determining a critical dimension at all azimuth angles and a wide range of incident angles in a single operation of capturing an image. Embodiments may apply orthogonal decomposition to the acquired data to accurately determine a selected critical dimension among critical dimensions of a structure.

According to an example embodiment, original data corresponding to an azimuth angle of 0 degrees to 360 degrees may be acquired in a single operation of capturing an image, and a two-dimensional image extracted from the original data may be orthogonally decomposed into a plurality of bases to determine a plurality of weights allocated by the plurality of bases. A critical dimension of a structure included in a region of a sample may be determined using a distribution of the plurality of weights according to the plurality of bases and/or a selected weight having the highest sensitivity to a critical dimension to be measured among the plurality of weights. Therefore, the critical dimension of the structure included in the sample may be accurately determined only by the single operation of capturing an image, without a process of repeatedly acquiring data, while changing an azimuth angle and an incident angle. In addition, only a critical dimension to be measured may be accurately determined, regardless of an interaction of critical dimensions affecting each other in a process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor measurement apparatus, comprising:
an illumination unit including a light source, and a polarizer disposed on a propagation path of light emitted from the light source;
an optical unit configured to direct the light passing through the polarizer to be incident onto a sample, and to transmit the light, reflected from the sample, to an image sensor; and
a controller configured to process an original image, output by the image sensor, to determine a critical dimension of a structure included in a region of the sample on which the light is incident, wherein:
the controller is configured to acquire a two-dimensional image on a back focal plane of an objective lens included in the optical unit, by processing the original image, and
the controller is configured to orthogonally decompose the two-dimensional image corresponding to a selected wavelength among wavelength bands of the light into a plurality of bases, to generate one-dimensional data including a plurality of weights corresponding to the plurality of bases, and to use the one-dimensional data to determine a selected critical dimension among critical dimensions of the structure.

2. The semiconductor measurement apparatus as claimed in claim 1, wherein the controller is configured to express the one-dimensional data as a distribution of the plurality of weights according to the plurality of bases, and to compare the distribution with reference data stored in a library to determine the selected critical dimension of the structure.

3. The semiconductor measurement apparatus as claimed in claim 1, wherein the controller is configured to select at least one basis having a sensitivity, higher than a predetermined first reference value with respect to the selected critical dimension, among the plurality of bases, and to compare a weight allocated to the selected basis with reference data stored in a library to determine the selected critical dimension of the structure.

4. The semiconductor measurement apparatus as claimed in claim 3, wherein the controller is configured to orthogonally decompose a first image representing an intensity difference of a polarization component of the light generated by the polarizer into the plurality of bases, and to determine the plurality of weights allocated to the plurality of bases.

5. The semiconductor measurement apparatus as claimed in claim 4, wherein the controller is configured to select at least one basis having a sensitivity, lower than a predetermined second reference value with respect to a change in a critical dimension, other than the selected critical dimension, among the plurality of bases.

6. The semiconductor measurement apparatus as claimed in claim 1, wherein a numerical aperture of the objective lens is 0.9 or more and less than 1.0.

7. The semiconductor measurement apparatus as claimed in claim 6, wherein an incident angle of light reflected from the sample and incident on the objective lens is 65 degrees or more.

8. The semiconductor measurement apparatus as claimed in claim 1, wherein the plurality of bases are selected from matrix decomposition or an orthogonal polynomial including at least one of a Zernike polynomial, a Legendre polynomial, or a Hermite polynomial.

9. The semiconductor measurement apparatus as claimed in claim 1, wherein a surface of the image sensor is disposed on a conjugate position with respect to a position of the back focal plane.

10. The semiconductor measurement apparatus as claimed in claim 1, wherein the controller is configured to acquire a first image representing an intensity difference of a polarization component of the light reflected from the sample, and a second image representing a phase difference of the polarization component of the light reflected from the sample, from the two-dimensional image, and to orthogonally decompose at least one of the first image or the second image.

11. The semiconductor measurement apparatus as claimed in claim 1, wherein the controller is configured to determine at least one wavelength having a sensitivity with respect to the selected critical dimension, higher than a predetermined reference value, among the wavelength bands of the light, as the selected wavelength.

12. The semiconductor measurement apparatus as claimed in claim 1, wherein the controller is configured to transform the original image into data of a two-dimensional frequency space to find a region in which a signal due to interference appears, and to inversely transform data included in the region to acquire the two-dimensional image on the back focal plane.

13. A semiconductor measurement apparatus, comprising:
an image sensor configured to receive light passing through a polarizer and then reflected from a sample, and to generate an image representing an interference pattern of the light;
an optical unit disposed on a path on which the image sensor receives the light; and
a controller configured to divide the image into a first image corresponding to an intensity difference of a polarization component of the light reflected from the sample, and a second image corresponding to a phase difference of the polarization component of the light reflected from the sample, and to orthogonally decompose at least one of the first image or the second image into a plurality of bases and a plurality of weights, wherein:
the controller is configured to use the plurality of weights to determine a critical dimension of a structure included in a region of the sample from which the light is reflected,
the light passing through the polarizer and then reflected from the sample is light having a single wavelength, and
the controller is configured to receive the image from the image sensor while light having a continuous wavelength band is reflected from the sample, and to acquire three-dimensional data in which the image is arranged along the wavelength band.

14. The semiconductor measurement apparatus as claimed in claim 13, wherein the optical unit includes an objective lens disposed adjacent to a surface of the sample, and a self-interference generator disposed adjacent to the image sensor.

15. (canceled)

16. The semiconductor measurement apparatus as claimed in claim 14, wherein:
each of pixels included in the first image and the second image includes a coordinate including a first component corresponding to a distance from an optical axis of light, and a second component corresponding to an angle from a reference axis, parallel to the surface of the sample, respectively, and
the first component is determined by an incident angle of light incident on the objective lens, and the second component is determined by an azimuth angle of the light incident on the objective lens.

17. The semiconductor measurement apparatus as claimed in claim 13, wherein the controller is configured to compare one-dimensional data representing a distribution of the plurality of weights with respect to the plurality of bases with reference data stored in a library, to determine the critical dimension of the structure.

18. The semiconductor measurement apparatus as claimed in claim 13, wherein the controller is configured to compare a weight for a selected basis among the plurality of bases with reference data stored in a library, to determine the critical dimension of the structure.

19. A semiconductor measurement apparatus, comprising:
an illumination unit including a light source, and a polarizer polarizing light emitted by the light source;
an optical unit including an objective lens disposed on a path on which the light passing through the polarizer propagates toward a sample, and a polarizing element polarizing the light reflected from the sample;
an image sensor configured to receive the light passing through the optical unit, and to generate an original image representing an interference pattern of light in a two-dimensional plane defined at a position of a pupil of the objective lens by a single shutter operation; and
a controller configured to apply orthogonal decomposition or matrix decomposition to the original image, to determine a critical dimension of a structure included in a region of the sample from which the light is reflected.

20. The semiconductor measurement apparatus as claimed in claim 19, wherein the image sensor is configured to acquire the original image representing an interference pattern of a polarization component of light at an azimuth angle of 0 degrees to 360 degrees by the single shutter operation.

21. The semiconductor measurement apparatus as claimed in claim 19, wherein the image sensor is configured to acquire the original image representing an interference pattern of a polarization component of light at an incident angle between 0 degrees and a maximum incident angle of the objective lens by the single shutter operation.

22. (canceled)
